(19) United States
(12) Patent Application Publication
(10) Pub. No.: US 2015/0006826 A1
(43) Pub. Date: Jan. 1, 2015

(54) STRAP-BASED MULTIPLEXING SCHEME FOR MEMORY CONTROL MODULE

(71) Applicant: Yean Kee Yong, Singapore (SG)

(72) Inventor: Yean Kee Yong, Singapore (SG)

(21) Appl. No.: 13/931,235

(22) Filed: Jun. 28, 2013

(51) Int. Cl. G11C 17/16

(52) U.S. Cl. CPC G11C 17/16
USPC 711/147

(57) ABSTRACT

Embodiments include integrated circuits (ICs), system-on-chips (SoCs), and related methods for a strap-based multiplexing scheme for a memory control module. In one embodiment, a memory control module may include a first memory controller coupled to a first bus including a first conductor configured to carry a first signal, and a second memory controller coupled to a second bus including a second conductor configured to carry a second signal. The memory control module may further include a fuse configured to have a fuse setting, and a strap register configured to store a register value. The memory control module may further include a multiplexer configured to selectively pass the first signal or the second signal responsive to the fuse setting and the register value. Other embodiments may be described and claimed.

### FIELD

Embodiments of the present invention relate generally to the technical field of memory. Specific embodiments relate to a memory control module with the ability to provide different memory controller configurations within a semiconductor die.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure. Unless otherwise indicated herein, the approaches described in this section are not prior art to the claims in the present disclosure and are not admitted to be prior art by inclusion in this section.

Memory controllers are often used to facilitate communication of data between a memory, such as a dynamic random access memory (DRAM), and one or more other devices. Some systems include two memory channels, with each channel having a separate memory controller. In some such systems, the memory controllers may be included in a system on chip (SoC) for use in embedded systems or other applications. Different SoC part numbers (SKUs) are required for SoCs having different configurations of the memory controllers. The different SoCs require separate validation, production, documentation, and customer support, which involves significant expense.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 illustrates an example memory control module, in accordance with various embodiments.

FIG. 2 illustrates another example memory control module, in accordance with various embodiments.

FIG. 3 illustrates an example method for operating a memory control module, in accordance with various embodiments.

FIG. 4 illustrates an example system configured to employ the apparatuses and methods described herein, in accordance with various embodiments.

### DETAILED DESCRIPTION

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “module” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality. As used herein, “computer-implemented method” may refer to any method executed by one or more processors, a computer system having one or more processors, a mobile device such as a smartphone (which may include one or more processors), a tablet, laptop computer, a set-top box, a gaming console, and so forth.

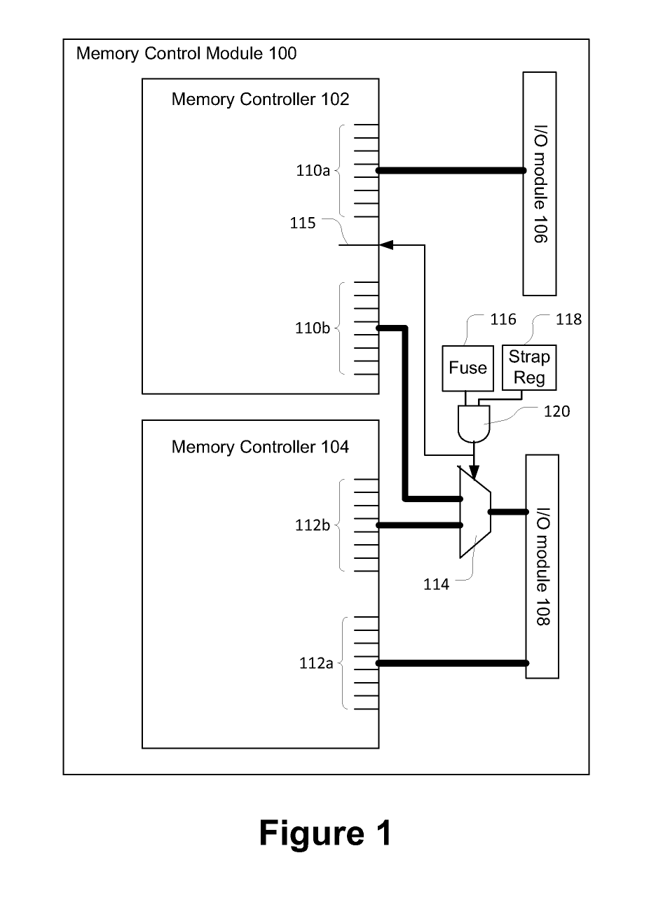

FIG. 1 illustrates a memory control module 100 in accordance with various embodiments. Memory control module 100 may be included in an integrated circuit on a semiconductor die. Memory control module 100 may be a multi-channel memory control module (e.g., a dual-channel memory control module) including a first memory controller 102 and a second memory controller 104. Memory control module 100 may further include a first input/output (I/O) module 106 coupled to the first memory controller 102 and a second I/O module 108 coupled to the second memory controller 104. The first memory controller 102 may be associated with a first memory channel of the memory control module 100, while the second memory controller 104 may be associated with a second memory channel of the memory control module 100.

The first memory controller 102 and second memory controller 104 may be coupled to respective groups of one or more memory devices (not shown), such as dynamic random access memory (DRAM) devices. In some embodiments, the DRAM devices may be organized into ranks. In some embodiments, the memory devices may be double data rate (DDR) memory devices, such as memory devices compatible with the JEDEC DDR3 standard.

The memory controllers 102 and 104 may facilitate writing data to and/or reading data from the memory devices. The I/O modules 106 and 108 may facilitate communication between the memory control module 100 and other devices (e.g., one or more processors, not shown) to enable the other devices to read and/or write data from memory devices controlled by memory control module 100.

In some embodiments, the memory control module 100 may be packaged in a system-on-chip (SoC) with one or more processors and/or other devices. In some embodiments, one or more of the memory devices (e.g., DRAM devices) may be included in the SoC. Alternatively, or additionally, one or more of the memory devices may be external to the SoC. The SoC may include a plurality of external pins, such as one or more pins to connect the SoC to the memory devices, and/or one or more power supply pins to receive electrical power.

In various embodiments, the first memory controller 102 may be coupled to buses 110a-b configured to carry respective signals, and the second memory controller 104 may be coupled to buses 112a-b configured to carry respective signals. The buses 110a-b and 112a-b may include, for example, conductors configured to carry a data signal (DQ), an error correction coding (ECC) signal, a chip select signal associated with a rank of the associated memory controller 102 or 104, and/or an on-die termination (ODT) signal associated with a rank of the associated memory controller 102 or 104. In some embodiments, one or more of the signals carried by the buses 110a-b and/or 112a-b may be DDR signals, such as DDR3 signals.

The buses 110a-b may include a bus 110a having one or more conductors that are coupled to the first memory controller 104, and a bus 110b having one or more conductors that are coupled to a multiplexer 114 of the memory control module 100. The buses 112a-b may include a bus 112a having one or more conductors that are coupled to the second I/O module, and a bus 112b having one or more conductors that are coupled to the multiplexer 114. In other embodiments, all of the signals communicated between the second memory controller 104 and the I/O module 108 may be multiplexed with signals of the first memory controller 104 (e.g., the memory control module 100 may include bus 112b coupled to multiplexer 114, but may not include bus 112a). Although the multiplexer 114 is shown in FIG. 1 as a single multiplexer 114, it will be understood that a plurality of multiplexers may be included in the memory control module 100 and coupled to different groups of one or more conductors of bus 110b or 112b.

In various embodiments, the memory control module 100 may further include a fuse 116 and a strap register 118 coupled to the multiplexer 114 (e.g., by an AND gate 120). The fuse 116 may have a fuse setting (e.g., a logic 0 or a logic 1), and the strap register 118 may store a register value (e.g., a logic 0 or a logic 1). The multiplexer 114 may selectively pass the signals on the bus 110b or the signals on the bus 112b, e.g., to the second I/O module 108, responsive to the fuse setting and the register value. For example, in some embodiments, the fuse 116 and strap register 118 may be coupled to respective inputs of the AND gate 120, and an output of the AND gate 120 may be coupled to an input select terminal 122 of the multiplexer.

In some such embodiments, the multiplexer 114 may pass the signals on the bus 112b, e.g., to the second I/O module 108, if the output of the AND gate 120 is a logic 0, and may pass the signals on the bus 110b, e.g., to the second I/O module 108, if the output of the AND gate is a logic 1. Accordingly, the multiplexer 114 may pass the signals on the bus 112b coupled to the second memory controller 104, e.g., to the second I/O module 108, if the fuse setting is a logic 0 or if the fuse setting is a logic 1 and the register value is a logic 0, and may pass the signals on the bus 110b coupled to the first memory controller 102, e.g., to the second I/O module 108, if the fuse setting is a logic 1 and the register value is a logic 1. It will be apparent that other schemes for controlling the multiplexer 114 based on the fuse setting and register value may be used in other embodiments.

In various embodiments, the memory control module 100 may operate in a first mode when the multiplexer 114 passes the signals on the bus 112b of the second memory controller 104, and may operate in a second mode when the multiplexer 114 passes the signals on the bus 110b of the first memory controller 102. In the first mode, both memory controllers 102 and 104 may be active and the memory control module 100 may use both the first and second memory channels. In the second mode, the second memory controller 104 may be deactivated, and the memory controller module 100 may only use the first memory channel (e.g., via the first memory controller 102). In the second mode, the bus 110b of the first memory controller 102 may be connected, e.g., to the second I/O module 108 (via the multiplexer 114). Accordingly, the first I/O module 106 may not need dedicated contacts for the bus 110b of the first memory controller 102.

In various embodiments, the bus 110b coupled to the first memory controller 102 may enable additional functionality for the first memory controller 102 during the second mode. For example, in some embodiments, the bus 110a of the first memory controller 102 may include conductors to communicate data signals (e.g., DQ signals) between the first memory controller 102 and the first I/O module 106. In some embodiments, the bus 110b may include one or more conductors used for ECC of the data signals on the data contacts of first memory controller 102. Accordingly, ECC may be enabled in the second mode. In this example, the second mode may also be referred to as the ECC mode of the memory control module 100, and the first mode may also be referred to as the non-ECC mode of the memory control module 100. Accordingly, the memory control module 100 may operate in the non-ECC mode using two memory channels but without using ECC, or may operate in the ECC mode using one memory channel with ECC enabled.

In some embodiments, the first memory controller 102 may be coupled to a mode select conductor 115 that is coupled to the output of the AND gate 120 to notify the first memory controller 102 in which mode the memory control module 100 is operating. Accordingly, the first memory controller 102 may activate the functionality provided by the bus 110b during the second mode.

Although the memory control module 100 is shown with two memory channels, in other embodiments the memory control module 100 may include more than two memory channels. The additional memory channels may or may not be multiplexed similar to the first and/or second memory channels.

In some embodiments, the conductors of the bus 112b of the second memory controller 104 that are multiplexed with the contacts 110b of the first memory controller 102 may be used to carry data signals. In other embodiments, the conductors of the bus 112b may carry another type of signal.

In some embodiments, the fuse setting of the fuse 116 may be set prior to shipping the memory control module 100 to a customer (e.g., a manufacturer of a device that employs the memory control module 100). For example, the fuse setting may be set by a manufacturer of the memory control module 100. In some embodiments, the fuse setting may not be alterable by the customer.

In various embodiments, the register value may be set by strapping the strap register 118 (e.g., to a voltage). For example, the strap may be a hard strap, in which the strap register is hard-wired to another component (e.g., an element on a printed circuit board (PCB)) to provide the strap register 118 with the register value. In other embodiments, the strap may be a soft strap, in which the register value is provided by software and/or firmware upon boot-up of the memory control module 100. In some embodiments, the strapping of the strap register 118 may be set by the customer.

Accordingly, the manufacturer of the memory control module 100 may set the fuse setting to a logic 1 to enable the customer to select whether the memory control module 100 operates in the first mode or second mode by strapping the strap register 118. Alternatively, the manufacturer of the memory control module 100 may set the fuse setting to a logic 0 to disable the option of operating the memory control module 100 in the second mode (e.g., ensuring that the memory control module 100 will operate in the first mode). The manufacturer may set the fuse setting, for example, based on the needs of the customer.

Accordingly, the fuse 116 and strap register 118 may provide flexibility in the implementation and features of the memory control module 100. Thus, a single memory control module product may be adapted for use with customers having different needs (e.g., customers that require ECC and customers that do not require ECC). This may save substantial costs (e.g., validation, production, documentation, and customer support costs) compared with providing separate products for customers with different needs.

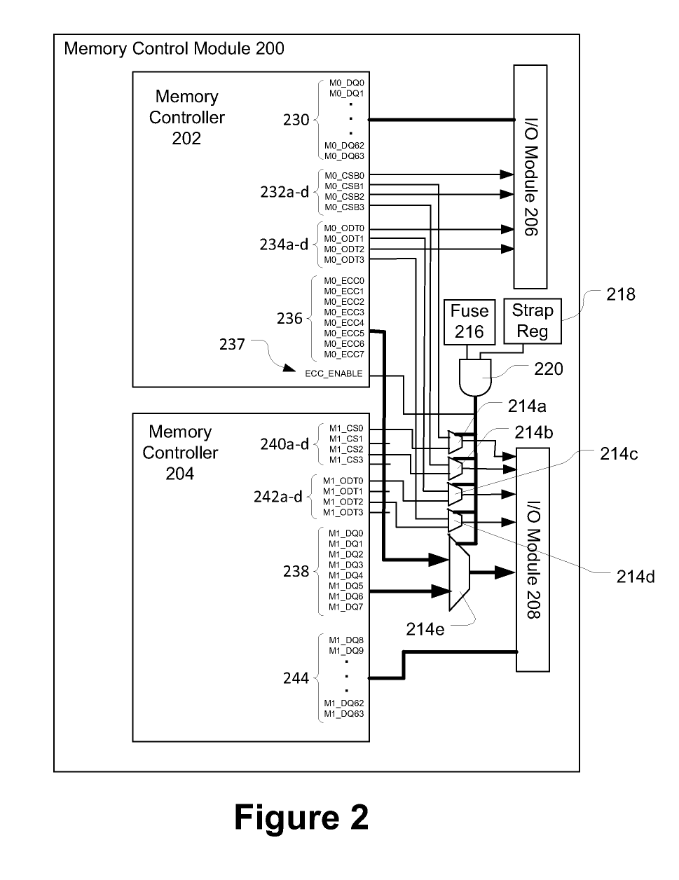

FIG. 2 illustrates another example memory control module 200 in accordance with various embodiments. Memory control module 200 may include a first memory controller 202 and a second memory controller 204. Memory control module 200 may further include a first I/O module 206 coupled to the first memory controller 202 and a second I/O module 208 coupled to the second memory controller 204. The first memory controller 202 may be associated with a first memory channel of the memory control module 200, while the second memory controller 204 may be associated with a second memory channel of the memory control module 200.

The first memory controller 202 may be coupled to data conductors 230 (e.g., M0_DQ0 to M0_DQ63) to carry data signals, channel select conductors 232a-d (e.g., M0_CSB0, M0_CSB1, M0_CSB2, and M0_CSB3, respectively) to carry channel select signals, ODT conductors 234a-d (e.g., M0_ODT0, M0_ODT1, M0_ODT2, and M0_ODT3, respectively) to carry ODT signals, ECC conductors 236 (e.g., M0_ECC0 to M0_ECC7) to carry ECC signals, and an ECC enable conductor 237 to carry an ECC enable signal. The second memory controller 204 may be coupled to data conductors 238 (e.g., M1_DQ0 to M1_DQ7), channel select conductors 240a-d (e.g., M1_CSB0, M1_CSB1, M1_CSB2, and M1_CSB3, respectively), ODT conductors 242a-d (e.g., M1_ODT0, M1_ODT1, M1_ODT2, and M1_ODT3, respectively), and additional data conductors 244 (e.g., M1_DQ8 to M1_DQ63). In some embodiments, the memory controllers 202 and/or 204 may include a greater or fewer number of data conductors, channel select conductors, ODT conductors, and/or ECC conductors than the number shown in FIG. 2. Additionally, or alternatively, the memory controllers 202 and/or 204 may include other types of conductors in some embodiments. The conductors coupled to the first memory controller 202 and/or second memory controller 204 may be included in one or more buses.

The channel select conductors 232a-d may be associated with respective ranks of the first memory controller 202, and the channel select conductors 240a-d may be associated with respective ranks of the second memory controller 204. The ranks may correspond to different groups of one or more memory devices (e.g., DRAM devices) that are coupled to the respective memory controller 202 or 204. The channel select conductors 232a-d and 240a-d may carry a channel select signal to indicate which rank of the respective memory controller is being used. The ODT conductors 234a-d and 242a-d may carry an ODT signal associated with the respective ranks that is used for communicating data signals with that rank (e.g., when the rank is active).

The memory control module 200 may further include multiplexers 214a-e, a fuse 216, and a strap register 218. The fuse 216 and strap register 218 may be coupled to inputs of an AND gate 220, and an output of the AND gate 220 may be coupled to respective input select terminals of the multiplexers 214a-e. The fuse 216 may have a fuse setting (e.g., a logic 0 or a logic 1), and the strap register 218 may store a register value (e.g., a logic 0 or a logic 1).

In various embodiments, the data conductors 230, channel select conductors 232a and 232c, and ODT conductors 234a and 234c of the first memory controller 202 may be coupled to the first I/O module 206. The ECC conductors 236 of the first memory controller 202 and the data conductors 238 of the second memory controller 204 may be coupled to respective inputs of the multiplexer 214e. The multiplexer 214e may be similar to the multiplexer 114 of FIG. 1.

The channel select contact 232b of the first memory controller 202 and the channel select contact 240a of the second memory controller 204 may be coupled to respective inputs of the multiplexer 214a. The channel select contact 232d of the first memory controller 202 and the channel select contact 240c of the second memory controller 204 may be coupled to respective inputs of the multiplexer 214b. The ODT contact 234b of the first memory controller 202 and the ODT contact 234a of the second memory controller 204 may be coupled to respective inputs of the multiplexer 214c. The ODT contact 234d of the first memory controller 202 and the ODT contact 234c of the second memory controller 204 may be coupled to respective inputs of the multiplexer 214d. The output terminals of the multiplexers 214a-e may be coupled to the second I/O module 208.

In some embodiments, the channel select conductors 240b and 24d and the ODT conductors 242b and 242d may not be coupled to the second I/O module 208. Accordingly, the second memory controller 204 may operate using only two of four available ranks. In other embodiments, the second memory controller 204 may only include as many channel select conductors and ODT conductors as the number of available ranks.

In various embodiments, the memory control module 200 may be in either an ECC mode or a non-ECC mode based on the fuse setting of the fuse 216 and the register value of the strap register 218. For example, the memory control module 200 may be in the non-ECC mode if the fuse setting is a logic 0 or if the fuse setting is a logic 1 and the register value is a logic 0, and may be in the ECC mode if the fuse setting is a logic 1 and the register value is a logic 1.

The ECC enable contact 237 of the first memory control module 200 may be coupled to the output of the AND gate 220 to notify the ECC enable contact 237 whether the memory control module 200 is in the ECC mode or the non-ECC mode. Accordingly, the ECC functionality of the memory control module 200 may be enabled in the ECC mode and disabled in the non-ECC mode.

In the non-ECC mode of the memory control module 200, the multiplexers 114a-e may connect the respective conductors of the second memory controller 204 (e.g., the data conductors 238, chip select conductors 240a and 240c, and ODT conductors 242a and 242c) to the second I/O module 208. The memory control module 200 may operate using both the first and second memory channels in the non-ECC mode, with both the first memory controller 202 and second memory controller 204 active. The first and second memory channels may both have two available ranks in the non-ECC mode.

In the ECC mode of the memory control module 200, the multiplexers 114a-e may connect the respective conductors of the first memory controller 202 (e.g., the ECC conductors 236, channel select conductors 232b and 232d, and ODT conductors 234b and 234d) to the second I/O module 208. In the ECC mode, the second memory controller 204 may be deactivated, and the memory control module 200 may operate using one memory channel (e.g., the first memory channel via the first memory controller 202). The first memory channel may have ECC enabled and may have four available ranks. Accordingly, the memory control module 200 may provide greater memory bandwidth on the first memory channel in the ECC mode than in the non-ECC mode, thereby compensating for the unavailability of the second memory channel during the ECC mode.

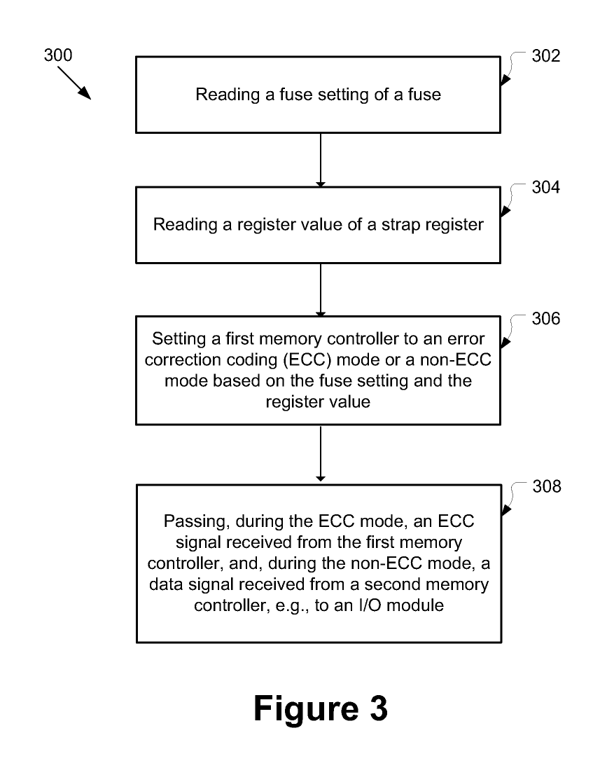

FIG. 3 illustrates a method 300 of operating a memory control module (e.g., memory control module 100 or memory control module 200) in accordance with various embodiments.

At block 302, method 300 may include reading a fuse setting of a fuse. The fuse may be similar to fuse 116 or 216 in some embodiments. The fuse setting may be either a logic 0 or a logic 1 in some embodiments.

At block 304, method 300 may include reading a register value of a strap register. The strap register may be similar to strap register 118 or 218 in some embodiments. The register value may be either a logic 0 or a logic 1 in some embodiments.

At block 306, the method 300 may include setting a first memory controller (e.g., memory controller 102 or 202) to an ECC mode or a non-ECC mode based on the fuse setting and the register value.

At block 308, method 300 may include passing, during the ECC mode, an ECC signal received from the first memory controller, and, during the non-ECC mode, a data signal received from a second memory controller (e.g., memory controller 104 or 204). The ECC signal and/or data signal may be passed, e.g., to an I/O module (e.g., I/O module 108 or 208).

In some embodiments, reading the fuse setting at block 302 and reading the register value at block 304 may be performed by a logic gate (e.g., AND gate 120 or 220) of the memory control module. An output of the logic gate may be coupled to the first memory controller to set the first memory controller to the ECC mode or the non-ECC mode at block 306 and/or to an input select terminal of a multiplexer (e.g., multiplexer 114 or 214e) to control which of the ECC signal or data signal is passed to the I/O module at block 308.

In some embodiments, the data signal from the second memory controller may be passed to the I/O module at block 308 if the fuse setting is a logic 0 or if the fuse setting is a logic 1 and the register value is a logic 0, and the ECC signal from the first memory controller may be passed to the I/O module at block 308 if the fuse setting is a logic 1 and the register value is a logic 1.

In some embodiments, the method 300 may further include receiving a first chip select signal associated with a first rank of the first memory controller, receiving a second chip select signal associated with a second rank of the second memory controller, and passing a selected one of the first or second chip select signal to the I/O module. The selected one of the first or second chip select signal may be determined based on the fuse setting and the register value. In some embodiments, receiving the first and second chip select signals and passing the selected one of the first or second chip select signal, e.g., to the I/O module, may be performed by a multiplexer (e.g., multiplexer 214a or 214b).

In some embodiments, the method 300 may further include receiving a first ODT signal associated with the first rank from the first memory controller, receiving a second ODT signal associated with the second rank from the second memory controller, and passing a selected one of the first or second ODT signal to the I/O module. The selected one of the first or second ODT signal may be determined based on the fuse setting and the register value. In some embodiments, receiving the first and second ODT signals and passing the selected one of the first or second ODT signal, e.g., to the I/O module, may be performed by a multiplexer (e.g., multiplexer 214c or 214d).

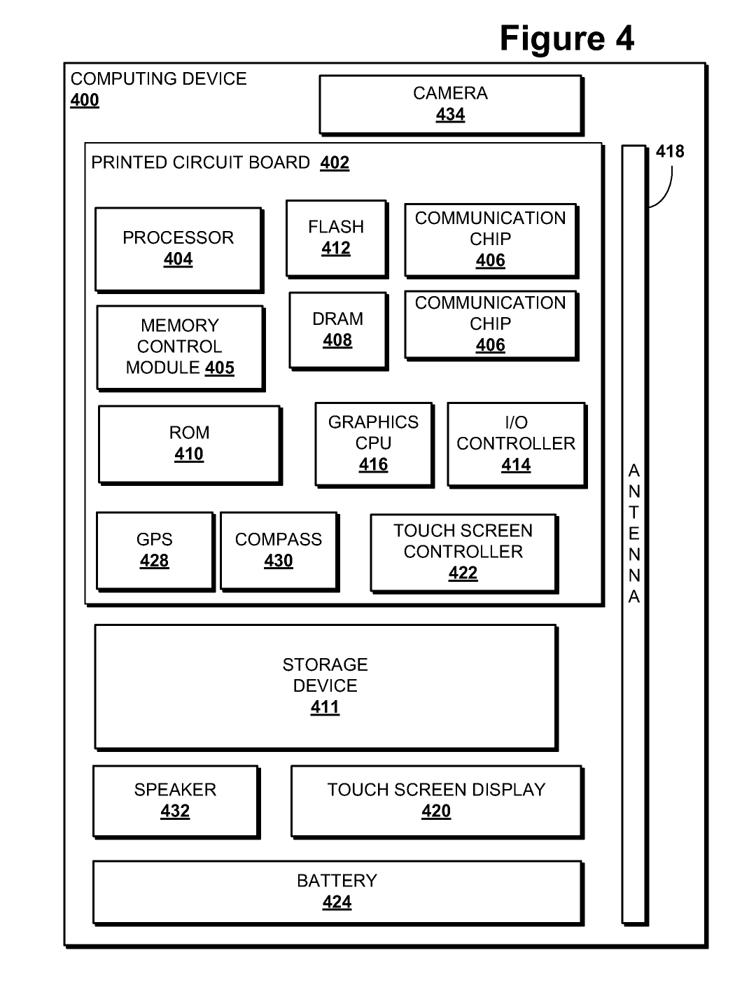

FIG. 4 illustrates an example computing device 400 which may employ the apparatuses and/or methods described herein (e.g., memory control module 100 or 200, method 300), in accordance with various embodiments. As shown, computing device 400 may include a number of components, such as one or more processor(s) 404 (one shown) and at least one communication chip 406. In various embodiments, the one or more processor(s) 404 each may include one or more processor cores. In various embodiments, the at least one communication chip 406 may be physically and electrically coupled to the one or more processor(s) 404. In further implementations, the communication chip 406 may be part of the one or more processor(s) 404. In various embodiments, computing device 400 may include printed circuit board (PCB) 402. For these embodiments, the one or more processor(s) 404 and communication chip 406 may be disposed thereon. In alternate embodiments, the various components may be coupled without the employment of PCB 402.

Depending on its applications, computing device 400 may include other components that may or may not be physically and electrically coupled to the PCB 402. These other components include, but are not limited to, memory control module 405, volatile memory (e.g., DRAM 408), non-volatile memory such as read only memory 410 (ROM) and storage device 411, an I/O controller 414, a digital signal processor (not shown), a crypto processor (not shown), a graphics processor 416, one or more antenna 418, a display (not shown), a touch screen display 420, a touch screen controller 422, a battery 424, an audio codec (not shown), a video codec (not shown), a global positioning system (GPS) device 428, a compass 430, an accelerometer (not shown), a gyroscope (not shown), a speaker 432, a camera 434, and a mass storage device (such as hard disk drive, a solid state drive, compact disk (CD), digital versatile disk (DVD))(not shown), and so forth. In various embodiments, the processor 404 may be integrated on the same die with other components to form a System on Chip (SoC).

In various embodiments, rather than or in addition to storage device 412, computing device 400 may include resident non-volatile memory, e.g., flash memory 412. In some embodiments, the one or more processor(s) 404 and/or flash 412 may include associated firmware (not shown) storing programming instructions configured to enable computing device 400, in response to execution of the programming instructions by one or more processor(s) 404, to practice all or selected aspects of the methods described herein (e.g., method 400). In various embodiments, these aspects may additionally or alternatively be implemented using hardware separate from the one or more processor(s) 404 or flash memory 412.

In various embodiments, memory control module 405 may include memory control module 100 or 200 described herein. The memory control module 405 may be used to read data from, or write data to, the DRAM 408, flash memory 412, and/or storage device 411. In embodiments, the memory control module 405 may practice method 300.

In some embodiments, memory control module 405 may be included in a memory controller hub (MCH) of the computing device 400. The memory control module 405 may additionally or alternatively be included in one or more other components of the computing device 400, e.g., one or more of processors 404. In some embodiments, the memory control module 405 may be packaged with one or more of processors 404 to form a system on chip (SoC).

The communication chips 406 may enable wired and/or wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to IEEE 702.20, General Packet Radio Service (GPRS), Evolution Data Optimized (Ev-DO), Evolved High Speed Packet Access (HSPA+), Evolved High Speed Downlink Packet Access (HSDPA+), Evolved High Speed Uplink Packet Access (HSUPA+), Global System for Mobile Communications (GSM), Enhanced Data rates for GSM Evolution (EDGE), Code Division Multiple Access (CDMA), Time Division Multiple Access (TDMA), Digital Enhanced Cordless Telecommunications (DECT), Bluetooth, derivatives thereof, as well as any other wireless protocols that are designated as 3G, 4G, 5G, and beyond. The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

In various implementations, the computing device 400 may be a laptop, a netbook, a notebook, an ultrabook, a smartphone, a computing tablet, a personal digital assistant (PDA), an ultra-mobile PC, a mobile phone, a desktop computer, a server, a printer, a scanner, a monitor, a set-top box, an entertainment control unit (e.g., a gaming console or automotive entertainment unit), a digital camera, an appliance, a portable music player, or a digital video recorder. In further implementations, the computing device 400 may be any other electronic device that processes data.

### EXAMPLES

Example 1 is an integrated circuit on a semiconductor die comprising: a first memory controller coupled to a first bus including a first conductor configured to carry a first signal; a second memory controller coupled to a second bus including a second conductor configured to carry a second signal; a fuse configured to have a fuse setting; a strap register configured to store a register value; and a multiplexer coupled to the first conductor, the second conductor, the fuse, and the strap register, and configured to selectively pass either the first signal or the second signal responsive to the fuse setting and the register value.

Example 2 is the integrated circuit of Example 1, wherein the first conductor is configured to carry an error correction coding (ECC) signal for ECC of data signals associated with the first memory controller.

Example 3 is the integrated circuit of Example 2, wherein the second conductor is a data conductor for data signals associated with the second memory controller.

Example 4 is the integrated circuit of Example 1, wherein the first conductor is a configured to carry a first chip select signal associated with a first rank of the first memory controller, and the second conductor is configured to carry a second chip select signal associated with a second rank of the second memory controller.

Example 5 is the integrated circuit of Example 4, wherein the multiplexer is a first multiplexer, and wherein: the first bus coupled to the first memory controller further includes a third conductor configured to carry a first on-die termination (ODT) signal associated with the first rank of the first memory controller; the second bus coupled to the second memory controller further includes a fourth conductor configured to carry a second ODT signal associated with the second rank of the second memory controller; and the integrated circuit further includes a second multiplexer coupled with the third conductor, the fourth conductor, the fuse, and the strap register, and configured to receive the first and second ODT signals and to selectively pass the first ODT signal or the second ODT signal responsive to the fuse setting and the register value.

Example 6 is the integrated circuit of any of Examples 1 to 5, wherein the multiplexer is configured to: pass the second signal if the fuse setting has a first logic value or if the fuse setting has a second logic value and the register value has a third logic value; and pass the first signal if the fuse setting has the second logic value and the register value has a fourth logic value.

Example 7 is the integrated circuit of Example 1, further comprising a strapping contact coupled with the strap register and configured to provide the strap register with the register value.

Example 8 is the integrated circuit of Example 1, wherein the register value is provided by a soft strap upon boot-up of the integrated circuit.

Example 9 is the integrated circuit of Example 1, wherein the first signal or the second signal is selectively passed to an I/O module, and wherein the first memory controller is further coupled to a plurality of data conductors configured to pass data signals to another I/O module.

Example 10 is a method for operating a memory control module comprising: reading a fuse setting of a fuse; reading a register value of a strap register;

setting a first memory controller to an error correction coding (ECC) mode or a non-ECC mode based on the fuse setting and the register value; and passing, during the ECC mode, an ECC signal received from the first memory controller, and, during the non-ECC mode, a data signal received from a second memory controller.

Example 11 is the method of Example 10, further comprising receiving a first chip select signal associated with a first rank of the first memory controller; receiving a second chip select signal associated with a second rank of the second memory controller; and

passing a selected one of the first or second chip select signal, based on the fuse setting and the register value.

Example 12 is the method of Example 11, further comprising: receiving a first on-die termination (ODT) signal associated with the first rank from the first memory controller; receiving a second ODT signal associated with the second rank from the second memory controller; and passing a selected one of the first or second ODT signal, based on the fuse setting and the register value.

Example 13 is the method of Example 10, wherein the setting the first memory controller to the ECC mode or the non-ECC mode includes: setting the first memory controller to the non-ECC mode if the fuse setting has a first logic value or if the fuse setting has a second logic value and the register value has a third logic value; and setting the first memory controller to the ECC mode if the fuse setting has the second logic value and the register value has a fourth logic value.

Example 14 is the method of any of Examples 10 to 13, wherein the passing comprises selectively passing the ECC signal or the data signal to an I/O module, and wherein the method further comprises passing data signals from the first memory controller to another I/O module.

Example 15 is a system-on-chip (SoC) comprising a processor and a memory control module coupled to the processor. The memory control module includes: a first input/output (I/O) module; a second I/O module; a first memory controller associated with a first memory channel and coupled to a plurality of data conductors configured to transmit first channel data signals to the first I/O module, and a plurality of error correction coding (ECC) conductors configured to transmit ECC signals associated with the first channel data signals; a second memory controller associated with a second memory channel and coupled to a plurality of data conductors configured to transmit second channel data signals; a fuse configured to have a fuse setting; a strap register configured to store a register value, wherein the memory control module is configured to be in an ECC mode or a non-ECC mode based on the fuse setting and the register value; and a multiplexer coupled to the ECC conductors and the data conductors coupled to the second memory controller. The multiplexer is configured to: pass the ECC signals to the second I/O module during the ECC mode of the memory control module; and pass the second channel data signals to the second I/O module during the non-ECC mode of the memory control module.

Example 16 is the SoC of Example 15, wherein the multiplexer is a first multiplexer, and wherein: the first memory controller is further coupled to a first chip select conductor configured to carry a first chip select signal associated with a first rank of the first memory controller; the second memory controller is further coupled to a second chip select conductor configured to carry a second chip select signal associated with a second rank of the second memory controller; and the memory control module further includes a second multiplexer coupled to the first and second chip select conductors. The second multiplexer is configured to: pass the first chip select signal to the second I/O module during the ECC mode of the memory control module; and pass the second chip select signal to the second I/O module during the non-ECC mode of the memory control module.

Example 17 is the SoC of Example 16, wherein: the first memory controller is further coupled to a first on-die termination (ODT) conductor configured to carry a first ODT signal associated with the first rank of the first memory controller; the second memory controller is further coupled to a second ODT conductor configured to carry a second ODT signal associated with the second rank of the second memory controller; and the memory control module further includes a third multiplexer coupled to the first and second ODT conductors. The third multiplexer is configured to: pass the first ODT signal to the second I/O module during the ECC mode of the memory control module; and pass the second ODT signal to the second I/O module during the non-ECC mode of the memory control module.

Example 18 is the SoC of Example 15, wherein the memory control module is in the non-ECC mode if the fuse setting has a first logic value or if the fuse setting has a second logic value and the register value has a third logic value, and the memory control module is in the ECC mode if the fuse setting has the second logic value and the register value has a fourth logic value.

Example 19 is the SoC of Example 15, further comprising an AND gate coupled to the fuse and the strap register and configured to output a control signal to the multiplexer to place the memory control module in the ECC mode or the non-ECC mode

Example 20 is the SoC of any of Examples 15 to 19, wherein the memory control module further comprises a strapping contact coupled to the strapping register and configured to be wired to a printed circuit board (PCB) element to provide the register value.

Example 21 is the SoC of any of Examples 15 to 19, wherein the register value is provided by a soft strap upon boot-up of the memory control module.

Although certain embodiments have been illustrated and described herein for purposes of description, this application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

What is claimed is:

1. An integrated circuit on a semiconductor die comprising:
a first memory controller coupled to a first bus including a first conductor configured to carry a first signal;
a second memory controller coupled to a second bus including a second conductor configured to carry a second signal;
a fuse configured to have a fuse setting;
a strap register configured to store a register value; and
a multiplexer coupled to the first conductor, the second conductor, the fuse, and the strap register, and configured to selectively pass either the first signal or the second signal responsive to the fuse setting and the register value.

2. The integrated circuit of claim 1, wherein the first conductor is configured to carry an error correction coding (ECC) signal for ECC of data signals associated with the first memory controller.

3. The integrated circuit of claim 2, wherein the second conductor is configured to carry data signals associated with the second memory controller.

4. The integrated circuit of claim 1, wherein the first conductor is configured to carry a first chip select signal associated with a first rank of the first memory controller, and the second conductor is configured to carry a second chip select signal associated with a second rank of the second memory controller.

5. The integrated circuit of claim 4, wherein the multiplexer is a first multiplexer, and wherein:
the first bus coupled to the first memory controller further includes a third conductor configured to carry a first on-die termination (ODT) signal associated with the first rank of the first memory controller;
the second bus coupled to the second memory controller further includes a fourth conductor configured to carry a second ODT signal associated with the second rank of the second memory controller; and
the integrated circuit further includes a second multiplexer coupled with the third conductor, the fourth conductor, the fuse, and the strap register, and configured to receive the first and second ODT signals and to selectively pass the first ODT signal or the second ODT signal responsive to the fuse setting and the register value.

6. The integrated circuit of claim 1, wherein the multiplexer is configured to:
pass the second signal if the fuse setting has a first logic value or if the fuse setting has a second logic value and the register value has a third logic value; and
pass the first signal if the fuse setting has the second logic value and the register value has a fourth logic value.

7. The integrated circuit of claim 1, further comprising a strapping contact coupled with the strap register and configured to provide the strap register with the register value.

8. The integrated circuit of claim 1, wherein the register value is provided by a soft strap upon boot-up of the integrated circuit.

9. The integrated circuit of claim 1, wherein the first signal or the second signal is selectively passed to an I/O module, and wherein the first memory controller is further coupled to a plurality of data conductors configured to pass data signals to another I/O module.

10. A method comprising:
reading a fuse setting of a fuse;
reading a register value of a strap register;
setting a first memory controller to an error correction coding (ECC) mode or a non-ECC mode based on the fuse setting and the register value; and
passing, during the ECC mode, an ECC signal received from the first memory controller, and, during the non-ECC mode, a data signal received from a second memory controller.

11. The method of claim 10, further comprising:
receiving a first chip select signal associated with a first rank of the first memory controller;
receiving a second chip select signal associated with a second rank of the second memory controller; and
passing a selected one of the first or second chip select signal, based on the fuse setting and the register value.

12. The method of claim 11, further comprising:
receiving a first on-die termination (ODT) signal associated with the first rank from the first memory controller;
receiving a second ODT signal associated with the second rank from the second memory controller; and
passing a selected one of the first or second ODT signal, based on the fuse setting and the register value.

13. The method of claim 10, wherein the setting the first memory controller to the ECC mode or the non-ECC mode includes:
setting the first memory controller to the non-ECC mode if the fuse setting has a first logic value or if the fuse setting has a second logic value and the register value has a third logic value; and
setting the first memory controller to the ECC mode if the fuse setting has the second logic value and the register value has a fourth logic value.

14. The method of claim 10, wherein the passing comprises selectively passing the ECC signal or the data signal to an I/O module, and wherein the method further comprises passing data signals from the first memory controller to another I/O module.

15. A system-on-chip (SoC) comprising:
a processor;
a memory control module coupled to the processor, the memory control module including:
a first input/output (I/O) module;
a second I/O module;
a first memory controller associated with a first memory channel and coupled to a plurality of data conductors configured to transmit first channel data signals to the first I/O module, and a plurality of error correction coding (ECC) conductors configured to transmit ECC signals associated with the first channel data signals;
a second memory controller associated with a second memory channel and coupled to a plurality of data conductors configured to transmit second channel data signals;
a fuse configured to have a fuse setting;
a strap register configured to store a register value, wherein the memory control module is configured to be in an ECC mode or a non-ECC mode based on the fuse setting and the register value; and
a multiplexer coupled to the ECC conductors and the data conductors coupled to the second memory controller and configured to:
pass the ECC signals to the second I/O module during the ECC mode of the memory control module; and
pass the second channel data signals to the second I/O module during the non-ECC mode of the memory control module.

16. The SoC of claim 15, wherein the multiplexer is a first multiplexer, and wherein:
the first memory controller is further coupled to a first chip select conductor configured to carry a first chip select signal associated with a first rank of the first memory controller;
the second memory controller is further coupled to a second chip select conductor configured to carry a second chip select signal associated with a second rank of the second memory controller; and
the memory control module further includes a second multiplexer coupled to the first and second chip select conductors and configured to:
pass the first chip select signal to the second I/O module during the ECC mode of the memory control module; and
pass the second chip select signal to the second I/O module during the non-ECC mode of the memory control module.

17. The SoC of claim 16, wherein:
the first memory controller is further coupled to a first on-die termination (ODT) conductor configured to carry a first ODT signal associated with the first rank of the first memory controller;
the second memory controller is further coupled to a second ODT conductor configured to carry a second ODT signal associated with the second rank of the second memory controller; and
the memory control module further includes a third multiplexer coupled to the first and second ODT conductors and configured to:
pass the first ODT signal to the second I/O module during the ECC mode of the memory control module; and
pass the second ODT signal to the second I/O module during the non-ECC mode of the memory control module.

18. The SoC of claim 15, wherein the memory control module is in the non-ECC mode if the fuse setting has a first logic value or if the fuse setting has a second logic value and the register value has a third logic value, and the memory control module is in the ECC mode if the fuse setting has the second logic value and the register value has a fourth logic value.

19. The SoC of claim 15, further comprising an AND gate coupled to the fuse and the strap register and configured to output a control signal to the multiplexer to place the memory control module in the ECC mode or the non-ECC mode

20. The SoC of claim 15, wherein the memory control module further comprises a strapping contact coupled to the strapping register and configured to be wired to a printed circuit board (PCB) element to provide the register value.

21. The SoC of claim 15, wherein the register value is provided by a soft strap upon boot-up of the memory control module.
